(19) United States
(12) Patent Application Publication
(10) Pub. No.: US 2025/0136849 A1
(43) Pub. Date: May 1, 2025

(54) ADHESIVE SHEET FOR TEMPORARILY FIXING ELECTRONIC COMPONENT

(71) Applicant: NITTO DENKO CORPORATION, Ibaraki-shi, Osaka (JP)

(72) Inventors: Shusaku UENO, Ibaraki-shi (JP); Kazumichi KATO, Ibaraki-shi (JP); Takamasa HIRAYAMA, Ibaraki-shi (JP)

(73) Assignee: NITTO DENKO CORPORATION, Ibaraki-shi, Osaka (JP)

(21) Appl. No.: 18/681,586

(22) PCT Filed: Mar. 30, 2022
(86) PCT No.: PCT/JP2022/015754

§ 371 Date: Feb. 6, 2024

(30) Foreign Application Priority Data
Sep. 9, 2021 (JP) 2021-147136

(51) Int. Cl. C09J 7/38; H01L 21/683

(52) U.S. Cl. CPC C09J 7/385; H01L 21/6836; C09J 2203/326; C09J 2301/302

(57) ABSTRACT

Provided is a pressure-sensitive adhesive sheet including a pressure-sensitive adhesive layer containing an acrylic pressure-sensitive adhesive, the pressure-sensitive adhesive sheet being excellent in characteristics under high temperature and optimum for temporary fixing of an electronic part. A pressure-sensitive adhesive sheet for temporarily fixing an electronic part of the present invention includes a pressure-sensitive adhesive layer containing an acrylic pressure-sensitive adhesive. The acrylic pressure-sensitive adhesive contains an acrylic polymer, and the pressure-sensitive adhesive layer has a coefficient of thermal expansion at from 200° C. to 210° C. of from 1×10⁻⁵/K to 500×10⁻⁵/K. In one embodiment, the pressure-sensitive adhesive layer has a coefficient of thermal expansion at from 230° C. to 240° C. of from 1×10⁻⁵/K to 500×10⁻⁵/K.

### TECHNICAL FIELD

The present invention relates to a pressure-sensitive adhesive sheet for temporarily fixing an electronic part.

### BACKGROUND ART

In a technology of flip-chip bonding including temporarily fixing a small electronic part (e.g., a mini LED or micro LED chip) onto a pressure-sensitive adhesive sheet and then mounting the electronic part on a circuit board, a method of arranging a plurality of electronic parts on the pressure-sensitive adhesive sheet at predetermined intervals, and collectively subjecting the parts to heating and joining has been known (e.g., Patent Literature 1). In the pressure-sensitive adhesive sheet to be used in such heating step, dimensional stability and heat resistance (in particular, low outgassing property at the time of the heating) for keeping a positional relationship between the arranged electronic parts are required (e.g., Patent Literature 2).

### CITATION LIST

### Patent Literature

[PTL 1] JP 6691184 B2
[PTL 2] JP 2015-170690 A

### SUMMARY OF INVENTION

### Technical Problem

The present invention has been made to solve the above-mentioned problems of the related art, and an object of the present invention is to provide a pressure-sensitive adhesive sheet including a pressure-sensitive adhesive layer containing an acrylic pressure-sensitive adhesive, the pressure-sensitive adhesive sheet being excellent in characteristics under high temperature and optimum for temporary fixing of an electronic part.

### Solution to Problem

According to the present invention, there is provided a pressure-sensitive adhesive sheet for temporarily fixing an electronic part, including a pressure-sensitive adhesive layer containing an acrylic pressure-sensitive adhesive, wherein the acrylic pressure-sensitive adhesive contains an acrylic polymer, and wherein the pressure-sensitive adhesive layer has a coefficient of thermal expansion at from 200° C. to 210° C. of from 1×10⁻⁵/K to 500×10⁻⁵/K.

In one embodiment, the pressure-sensitive adhesive layer has a coefficient of thermal expansion at from 230° C. to 240° C. of from 1×10⁻⁵/K to 500×10⁻⁵/K.

In one embodiment, the pressure-sensitive adhesive layer has a storage elastic modulus G′ at 200° C. of 0.05 MPa or more.

In one embodiment, the pressure-sensitive adhesive layer has a 5% weight loss temperature of from 320° C. to 400° C.

In one embodiment, the pressure-sensitive adhesive layer has a gel fraction of from 93% to 99.99%.

In one embodiment, the pressure-sensitive adhesive layer further contains an epoxy-based cross-linking agent, and the acrylic polymer contains a constituent unit derived from a carboxy group-containing monomer.

In one embodiment, the pressure-sensitive adhesive layer further contains an isocyanate-based cross-linking agent, and the acrylic polymer contains a constituent unit derived from a hydroxy group-containing monomer.

In one embodiment, the acrylic polymer contains a constituent unit derived from a polyfunctional monomer.

In one embodiment, the polyfunctional monomer is trimethylolpropane triacrylate.

In one embodiment, the acrylic pressure-sensitive adhesive further contains a cross-linking catalyst.

In one embodiment, the cross-linking catalyst is dioctyltin dilaurate or triethylenediamine.

In one embodiment, the acrylic polymer has a weight-average molecular weight Mw of from 600,000 to 1,600,000.

In one embodiment, the pressure-sensitive adhesive sheet further includes a base material, and the pressure-sensitive adhesive layer is arranged on at least one surface of the base material.

In one embodiment, the pressure-sensitive adhesive sheet is used in a flip-chip bonding step, a resin encapsulation step, and a rewiring layer formation step for a semiconductor device.

### Advantageous Effects of Invention

According to the present invention, the pressure-sensitive adhesive sheet including the pressure-sensitive adhesive layer containing the acrylic pressure-sensitive adhesive, the pressure-sensitive adhesive sheet being excellent in characteristics under high temperature and optimum for temporary fixing of an electronic part, can be provided.

### BRIEF DESCRIPTION OF DRAWINGS

FIG. 1 are each a schematic sectional view of a pressure-sensitive adhesive sheet according to one embodiment of the present invention.

### DESCRIPTION OF EMBODIMENTS

### A. Overall Configuration of Pressure-Sensitive Adhesive Sheet for Temporarily Fixing Electronic Part

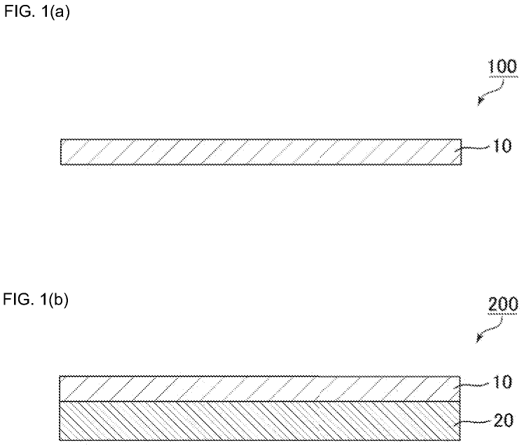

FIG. 1(a) is a schematic sectional view of a pressure-sensitive adhesive sheet for temporarily fixing an electronic part (hereinafter also simply referred to as “pressure-sensitive adhesive sheet”) according to one embodiment of the present invention. A pressure-sensitive adhesive sheet 100 includes a pressure-sensitive adhesive layer 10. The pressure-sensitive adhesive layer 10 contains an acrylic pressure-sensitive adhesive. In addition, the pressure-sensitive adhesive layer 10 has a coefficient of thermal expansion at from 200° C. to 210° C. of from 1×10⁻⁵/K to 500×10⁻⁵/K.

FIG. 1(b) is a schematic sectional view of a pressure-sensitive adhesive sheet according to another embodiment of the present invention. A pressure-sensitive adhesive sheet 200 further includes a base material 20, and the pressure-sensitive adhesive layer 10 is arranged on at least one surface of the base material 20.

The pressure-sensitive adhesive sheet may further include a layer except the pressure-sensitive adhesive layer 10 as required, though the layer is not shown. For example, another pressure-sensitive adhesive layer or a resin layer may be arranged. In addition, a separator, which is peelably arranged on the pressure-sensitive adhesive layer, may be arranged.

When the pressure-sensitive adhesive layer of the pressure-sensitive adhesive sheet of the present invention is bonded to SUS304 under an ambient temperature of 25° C., its pressure-sensitive adhesive strength is preferably from 0.1 N/20 mm to 20 N/20 mm, more preferably from 0.1 N/20 mm to 18 N/20 mm, still more preferably from 0.2 N/20 mm to 12 N/20 mm. When the pressure-sensitive adhesive strength falls within such ranges, a pressure-sensitive adhesive sheet that can preferably exhibit fixability and peelability can be obtained. As used herein, the pressure-sensitive adhesive strength refers to a pressure-sensitive adhesive strength measured by a method in conformity with JIS Z 0237:2000 (bonding conditions: one pass back and forth with a 2 kg roller, tensile rate: 300 mm/min, peel angle: 180°).

The thickness of the pressure-sensitive adhesive sheet is preferably from 1 μm to 200 μm, more preferably from 3 μm to 150 μm.

The pressure-sensitive adhesive sheet is used for temporary fixing of an electronic part. As used herein, the term “temporary fixing” refers to the fixing of the electronic part at such a level that predetermined processing (e.g., an encapsulation step) is allowed and peeling is also allowed. For example, when the pressure-sensitive adhesive strength falls within the above-mentioned ranges, a pressure-sensitive adhesive sheet that can temporarily fix an electronic part can be obtained. The pressure-sensitive adhesive sheet is typically used in a step of performing heating at a predetermined temperature (e.g., 200° C. or more, preferably from 200° C. to 300° C., more preferably from 230° C. to 270° C.). The pressure-sensitive adhesive sheet of the present invention is advantageous in that the pressure-sensitive adhesive sheet is reduced in dimensional changes even under high temperature. When the pressure-sensitive adhesive sheet is used, the processing of a plurality of electronic parts arranged on the pressure-sensitive adhesive sheet (e.g., processing involving heating such as encapsulation processing) can be performed while a positional relationship between the electronic parts is maintained. When heat resistance is taken into consideration, a silicone-based pressure-sensitive adhesive sheet has heretofore been frequently used. However, the pressure-sensitive adhesive sheet of the present invention is excellent in heat resistance as compared to the related-art silicone-based pressure-sensitive adhesive sheet, and hence can exhibit such excellent characteristics as described above even under a temperature of, for example, about 260° C. In one embodiment, the pressure-sensitive adhesive sheet is used in a flip-chip bonding step, a resin encapsulation step, and a rewiring layer formation step for a semiconductor device. In each of those usages, dimensional stability under heating is particularly required, and when the pressure-sensitive adhesive sheet of the present invention is used, each step can be performed with high productivity.

The size of the electronic part is, for example, from 1 μm² to 100 mm². In one embodiment, the plurality of electronic parts may be arranged on the pressure-sensitive adhesive sheet, and intervals therebetween are each, for example, from 1 μm to 10 mm.

### B. Pressure-Sensitive Adhesive Layer

As described above, the coefficient of thermal expansion of the pressure-sensitive adhesive layer at from 200° C. to 210° C. is from 1×10⁻⁵/K to 500×10⁻⁵/K. The coefficient of thermal expansion of the pressure-sensitive adhesive layer at from 200° C. to 210° C. is preferably from 1×10⁻⁵/K to 250×10⁻⁵/K, more preferably from 1×10⁻⁵/K to 150×10⁻⁵/K, still more preferably from 1×10⁻⁵/K to 100×10⁻⁵/K, still more preferably from 1×10⁻⁵/K to 60×10⁻⁵/K, particularly preferably from 1×10⁻⁵/K to 45×10⁻⁵/K. When the coefficient of thermal expansion falls within such ranges, the effect of the present invention becomes significant. The coefficient of thermal expansion of the pressure-sensitive adhesive layer may be controlled by the composition of a base polymer for forming the acrylic pressure-sensitive adhesive, the kind and content of a cross-linking agent to be added to the acrylic pressure-sensitive adhesive, and the like. The coefficient of thermal expansion may be analyzed by thermomechanical analysis (TMA). Specifically, the coefficient of thermal expansion is measured by a sample displacement amount in a predetermined temperature range (e.g., from 200° C. to 210° C. or from 230° C. to 240° C.) by increasing the temperature of the pressure-sensitive adhesive layer from 20° C. to 300° C. at a rate of 10° C./min in a tension mode under the conditions of a nitrogen gas flow rate of 50.0 ml/min and a load of 0.0196 N.

The coefficient of thermal expansion of the pressure-sensitive adhesive layer at from 230° C. to 240° C. is preferably from 1×10⁻⁵/K to 500×10⁻⁵/K, more preferably from 1×10⁻⁵/K to 350×10⁻⁵/K, still more preferably from 1×10⁻⁵/K to 200×10⁻⁵/K, still more preferably from 1×10⁻⁵/K to 150×10⁻⁵/K, still more preferably from 1×10⁻⁵/K to 100×10⁻⁵/K, particularly preferably from 1×10⁻⁵/K to 80×10⁻⁵/K. When the coefficient of thermal expansion falls within such ranges, the effect of the present invention becomes significant.

The storage elastic modulus G′ of the pressure-sensitive adhesive layer at 200° C. is preferably 0.05 MPa or more, more preferably 0.06 MPa or more, still more preferably 0.07 MPa or more. When the storage elastic modulus G′ falls within such ranges, there can be obtained a pressure-sensitive adhesive sheet, which can prevent the positional shift of an adherend (workpiece) even under high temperature and has a moderate pressure-sensitive adhesive property. Although the storage elastic modulus G′ of the pressure-sensitive adhesive layer at 200° C. is preferably as high as possible, its upper limit is, for example, 100 MPa, preferably 80 MPa. The storage elastic modulus G′ may be measured for an evaluation sample (pressure-sensitive adhesive layer) measuring 8 mm in diameter by 1 mm in thickness with a dynamic viscoelasticity-measuring apparatus under the following measurement conditions.
Strain: 0.05%
Frequency: 1 Hz
Measurement range: from −50° C. to 260° C.
Temperature increase rate: 5° C./min

The 5% weight loss temperature of the pressure-sensitive adhesive layer is preferably from 320° C. to 400° C., more preferably from 330° C. to 390° C., still more preferably from 340° C. to 380° C. When the 5% weight loss temperature falls within such ranges, a pressure-sensitive adhesive sheet reduced in outgas under heating can be obtained. The 5% weight loss temperature of the pressure-sensitive adhesive layer may be controlled by the composition of the base polymer for forming the acrylic pressure-sensitive adhesive, the kind and content of a cross-linking agent to be added to the acrylic pressure-sensitive adhesive, and the like. The term “5% weight loss temperature” refers to a temperature at the time when the weight of the pressure-sensitive adhesive layer is reduced by 5% with respect to an initial weight in thermogravimetric (TG) measurement under the following conditions.
Measurement temperature range: from 20° C. to 500° C.
Temperature increase rate: 10° C./min
Atmospheric gas: nitrogen
Gas flow rate: 25 ml/min

The gel fraction of the pressure-sensitive adhesive layer is preferably from 93% to 99.99%, more preferably from 94% to 99.99%, still more preferably from 95% to 99.99%. When the gel fraction falls within such ranges, there can be obtained a pressure-sensitive adhesive sheet, which can prevent the positional shift of an adherend (workpiece) even under high temperature and has a moderate pressure-sensitive adhesive property. The gel fraction of the pressure-sensitive adhesive layer may be controlled by adjusting the composition of the base polymer for forming the acrylic pressure-sensitive adhesive, the kind and content of a cross-linking agent to be added to the acrylic pressure-sensitive adhesive, the kind and content of a tackifier, and the like. A method of measuring the gel fraction is as described below.

About 0.5 g of a pressure-sensitive adhesive layer was sampled and precisely weighed (weight of a sample). The sample was wrapped in a mesh-like sheet (product name: “NTF-1122”, manufactured by Nitto Denko Corporation) and then immersed in 50 ml of toluene at room temperature (25° C.) for 1 week. After that, a solvent-insoluble content (content in the mesh-like sheet) was taken out from toluene and dried at 130° C. for about 2 hours. The dried solvent-insoluble content was weighed (weight after immersion and drying), and a gel fraction (wt %) was calculated by the following equation (a).

$$Gel fraction ( wt \% ) = [ ( weight after immersion and drying ) / ( weight of sample ) ] \times 100 \qquad ( a )$$

The thickness of the pressure-sensitive adhesive layer is preferably from 1 μm to 300 μm, more preferably from 3 μm to 250 μm, still more preferably from 3 μm to 100 μm, particularly preferably from 5 μm to 60 μm. In one embodiment, the thickness of the pressure-sensitive adhesive layer is set to 30 μm or less. When the pressure-sensitive adhesive layer having a small thickness is formed, a pressure-sensitive adhesive sheet, which can prevent the positional shift of an adherend (workpiece), can be obtained.

As described above, an acrylic pressure-sensitive adhesive is used as the pressure-sensitive adhesive for forming the pressure-sensitive adhesive layer.

### (Base Polymer)

The acrylic pressure-sensitive adhesive is, for example, an acrylic pressure-sensitive adhesive obtained by using an acrylic polymer (homopolymer or copolymer), which uses one kind or two or more kinds of (meth)acrylic acid alkyl esters as monomer components, as a base polymer. Specific examples of the (meth)acrylic acid alkyl ester include (meth)acrylic acid C1-20 alkyl esters, such as methyl (meth)acrylate, ethyl (meth)acrylate, propyl (meth)acrylate, isopropyl (meth)acrylate, butyl (meth)acrylate, isobutyl (meth)acrylate, s-butyl (meth)acrylate, t-butyl (meth)acrylate, pentyl (meth)acrylate, hexyl (meth)acrylate, heptyl (meth)acrylate, octyl (meth)acrylate, 2-ethylhexyl (meth)acrylate, isooctyl (meth)acrylate, nonyl (meth)acrylate, isononyl (meth)acrylate, decyl (meth)acrylate, isodecyl (meth)acrylate, undecyl (meth)acrylate, dodecyl (meth)acrylate, tridecyl (meth)acrylate, tetradecyl (meth)acrylate, pentadecyl (meth)acrylate, hexadecyl (meth)acrylate, heptadecyl (meth)acrylate, octadecyl (meth)acrylate, nonadecyl (meth)acrylate, and eicosyl (meth)acrylate. Of those, a (meth)acrylic acid alkyl ester having a linear or branched alkyl group having 4 to 18 carbon atoms may be preferably used. The content ratio of the constituent unit of the (meth)acrylic acid alkyl ester in the acrylic polymer is preferably from 70 parts by weight to 100 parts by weight, more preferably from 75 parts by weight to 99.9 parts by weight, still more preferably from 80 parts by weight to 99.9 parts by weight with respect to 100 parts by weight of the acrylic polymer.

The acrylic polymer may contain a constituent unit derived from any other monomer copolymerizable with the (meth)acrylic acid alkyl ester as required for the purpose of modification of cohesive strength, heat resistance, or cross-linkability, an improvement in dimensional stability of the pressure-sensitive adhesive layer, or the like. Examples of such monomer include the following monomers:
carboxy group-containing monomers including: ethylenically unsaturated monocarboxylic acids, such as acrylic acid (AA), methacrylic acid (MAA), and crotonic acid; and ethylenically unsaturated dicarboxylic acids, such as maleic acid, itaconic acid, and citraconic acid, and anhydrides thereof (such as maleic anhydride and itaconic anhydride);
hydroxy group-containing monomers including: hydroxyalkyl (meth)acrylates, such as 2-hydroxyethyl (meth)acrylate, 2-hydroxypropyl (meth)acrylate, 3-hydroxypropyl (meth)acrylate, and 2-hydroxybutyl (meth)acrylate; unsaturated alcohols, such as vinyl alcohol and allyl alcohol; and ether-based compounds, such as 2-hydroxyethyl vinyl ether, 4-hydroxybutyl vinyl ether, and diethylene glycol monovinyl ether;
amino group-containing monomers including aminoethyl (meth)acrylate, N,N-dimethylaminoethyl (meth)acrylate, and t-butylaminoethyl (meth)acrylate;
epoxy group-containing monomers including glycidyl (meth)acrylate, methylglycidyl (meth)acrylate, and allyl glycidyl ether;
cyano group-containing monomers including acrylonitrile and methacrylonitrile;
keto group-containing monomers including diacetone (meth)acrylamide, diacetone (meth)acrylate, vinyl methyl ketone, vinyl ethyl ketone, allyl acetoacetate, and vinyl acetoacetate;
monomers each having a nitrogen atom-containing ring including N-vinyl-2-pyrrolidone, N-methylvinylpyrrolidone, N-vinylpyridine, N-vinylpiperidone, N-vinylpyrimidine, N-vinylpiperazine, N-vinylpyrazine, N-vinylpyrrole, N-vinylimidazole, N-vinyloxazole, N-vinylmorpholine, N-vinylcaprolactam, and N-(meth)acryloylmorpholine;
alkoxysilyl group-containing monomers including 3-(meth)acryloxypropyltrimethoxysilane, 3-(meth)acryloxypropyltriethoxysilane, 3-(meth)acryloxypropylmethyldimethoxysilane, and 3-(meth)acryloxypropylmethyldiethoxysilane; and isocyanate group-containing monomers including (meth)acryloyl isocyanate, 2-(meth)acryloyloxyethyl isocyanate, and m-isopropenyl-α,α-dimethylbenzyl isocyanate.

Those monomers may be used alone or in combination thereof.

In one embodiment, the acrylic polymer contains a constituent unit derived from a carboxy group-containing monomer. The content ratio of the constituent unit derived from a carboxy group-containing monomer in the acrylic polymer is preferably from 1 part by weight to 20 parts by weight, more preferably from 2 parts by weight to 15 parts by weight, still more preferably from 3 parts by weight to 10 parts by weight with respect to 100 parts by weight of the acrylic polymer. In one embodiment, the acrylic polymer containing the constituent unit derived from a carboxy group-containing monomer is used in combination with an epoxy-based cross-linking agent. When the acrylic polymer containing the constituent unit derived from a carboxy group-containing monomer and the epoxy-based cross-linking agent are used in combination, a pressure-sensitive adhesive layer having excellent heat resistance and excellent dimensional stability under high temperature can be formed. In addition, the combined use of the acrylic polymer and the epoxy-based cross-linking s also in that a pressure-sensitive adhesive layer reduced in outgas can be formed. Those effects become significant when the content ratio of the constituent unit derived from a carboxy group-containing monomer is set within the above-mentioned ranges.

In one embodiment, the acrylic polymer contains a constituent unit derived from a hydroxy group-containing monomer. The content ratio of the constituent unit derived from a hydroxy group-containing monomer in the acrylic polymer is preferably from 0.01 part by weight to 10 parts by weight, more preferably from 0.05 part by weight to 8 parts by weight, still more preferably from 0.1 part by weight to 5 parts by weight with respect to 100 parts by weight of the acrylic polymer. In one embodiment, the acrylic polymer containing the constituent unit derived from a hydroxy group-containing monomer is used in combination with an isocyanate-based cross-linking agent. When the acrylic polymer containing the constituent unit derived from a hydroxy group-containing monomer and the isocyanate-based cross-linking agent are used in combination, a pressure-sensitive adhesive layer having excellent heat resistance and excellent dimensional stability under high temperature can be formed. Such effects become significant when the content ratio of the constituent unit derived from a hydroxy group-containing monomer is set within the above-mentioned ranges.

In one embodiment, the acrylic polymer contains a constituent unit derived from a polyfunctional (preferably trifunctional or more, more preferably trifunctional to hexafunctional) monomer. Examples of such monomer include trimethylolpropane triacrylate, pentaerythritol tetraacrylate, ditrimethylolpropane tetraacrylate, and dipentaerythritol pentaacrylate. Of those, trimethylolpropane triacrylate is preferred. The acrylic polymer containing the constituent unit derived from a polyfunctional monomer can form a pressure-sensitive adhesive layer, which has satisfactory cross-linkability, excellent heat resistance, excellent and dimensional stability under high temperature, and is suppressed in occurrence of outgassing by heating. The content ratio of the constituent unit derived from a polyfunctional monomer in the acrylic polymer is preferably from 0.001 part by weight to 5 parts by weight, more preferably from 0.002 part by weight to 3 parts by weight, still more preferably from 0.005 part by weight to 1 part by weight with respect to 100 parts by weight of the acrylic polymer.

The weight-average molecular weight of the acrylic polymer is preferably from 600,000 to 1, 600,000, more preferably from 800,000 to 1,500,000. When the weight-average molecular weight falls within such ranges, there can be formed a pressure-sensitive adhesive layer, which has excellent heat resistance and excellent dimensional stability under high temperature, and is suppressed in occurrence of outgassing by heating. The weight-average molecular weight may be measured by GPC (solvent: THF).

### (Additive)

The acrylic pressure-sensitive adhesive may contain any appropriate additive as required. Examples of the additive include a cross-linking agent, a cross-linking catalyst, a tackifier, a plasticizer, a pigment, a dye, a filler, an age resistor, a conductive material, an antistatic agent, a UV absorber, a light stabilizer, a peeling modifier, a softener, a surfactant, a flame retardant, and an antioxidant.

Examples of the cross-linking agent include an isocyanate-based cross-linking agent, an epoxy-based cross-linking agent, a melamine-based cross-linking agent, a peroxide-based cross-linking agent, a urea-based cross-linking agent, a metal alkoxide-based cross-linking agent, a metal chelate-based cross-linking agent, a metal salt-based cross-linking agent, a carbodiimide-based cross-linking agent, an oxazoline-based cross-linking agent, an aziridine-based cross-linking agent, and an amine-based cross-linking agent. Of those, an epoxy-based cross-linking agent or an isocyanate-based cross-linking agent is preferred.

Examples of the epoxy-based cross-linking agent include N,N,N′,N′-tetraglycidyl-m-xylenediamine, diglycidylaniline, 1,3-bis(N,N-glycidylaminomethyl)cyclohexane (manufactured by Mitsubishi Gas Chemical Company, Inc., product name: “TETRAD-C”), 1,6-hexanediol diglycidyl ether (manufactured by Kyoeisha Chemical Co., Ltd., product name: “Epolight 1600”), neopentyl glycol diglycidyl ether (manufactured by Kyoeisha Chemical Co., Ltd., product name: “Epolight 1500NP”), ethylene glycol diglycidyl ether (manufactured by Kyoeisha Chemical Co., Ltd., product name: “Epolight 40E”), propylene glycol diglycidyl ether (manufactured by Kyoeisha Chemical Co., Ltd., product name: “Epolight 70P”), polyethylene glycol diglycidyl ether (manufactured by NOF Corporation, product name: “EPIOL E-400”), polypropylene glycol diglycidyl ether (manufactured by NOF Corporation, product name: “EPIOL P-200”), sorbitol polyglycidyl ether (manufactured by Nagase ChemteX Corporation, product name: “Denacol EX-611”), glycerol polyglycidyl ether (manufactured by Nagase ChemteX Corporation, product name: “Denacol EX-314”), pentaerythritol polyglycidyl ether, polyglycerol polyglycidyl ether (manufactured by Nagase ChemteX Corporation, product name: “Denacol EX-512”), sorbitan polyglycidyl ether, trimethylolpropane polyglycidyl ether, adipic acid diglycidyl ester, o-phthalic acid diglycidyl ester, triglycidyl-tris(2-hydroxyethyl) isocyanurate, resorcin diglycidyl ether, bisphenol-S-diglycidyl ether, and an epoxy-based resin having two or more epoxy groups in a molecule thereof. The content of the epoxy-based cross-linking agent may be set to any appropriate amount in accordance with a desired pressure-sensitive adhesive strength, and the viscoelasticity, dimensional stability, and outgassing property of the pressure-sensitive adhesive layer, and is typically from 0.01 part by weight to 10 parts by weight, more preferably from 0.03 part by weight to 7 parts by weight with respect to 100 parts by weight of the base polymer.

Specific examples of the isocyanate-based cross-linking agent include: lower aliphatic polyisocyanates, such as butylene diisocyanate and hexamethylene diisocyanate; alicyclic isocyanates, such as cyclopentylene diisocyanate, cyclohexylene diisocyanate, and isophorone diisocyanate; aromatic isocyanates, such as 2,4-tolylene diisocyanate, 4,4′-diphenylmethane diisocyanate, and xylylene diisocyanate; and isocyanate adducts, such as a trimethylolpropane/tolylene diisocyanate trimer adduct (manufactured by Nippon Polyurethane Industry Co., Ltd., product name: “CORONATE L”), a trimethylolpropane/hexamethylene diisocyanate trimer adduct (manufactured by Nippon Polyurethane Industry Co., Ltd., product name: “CORONATE HL”), and an isocyanurate form of hexamethylene diisocyanate (manufactured by Nippon Polyurethane Industry Co., Ltd., product name: “CORONATE HX”). The content of the isocyanate-based cross-linking agent may be set to any appropriate amount in accordance with a desired pressure-sensitive adhesive strength, the elasticity, dimensional stability, and outgassing property of the pressure-sensitive adhesive layer, and the like, and is typically from 0.1 part by weight to 20 parts by weight, more preferably from 0.5 part by weight to 10 parts by weight with respect to 100 parts by weight of the base polymer.

In one embodiment, the acrylic pressure-sensitive adhesive contains a cross-linking catalyst. When the cross-linking catalyst is added, there can be formed a pressure-sensitive adhesive layer, which has excellent heat resistance and excellent dimensional stability under high temperature, and is suppressed in occurrence of outgassing by heating. When the isocyanate-based cross-linking agent is used, the addition of the cross-linking catalyst is particularly effective. Examples of the cross-linking catalyst include: metallic cross-linking catalysts, such as tetra-n-butyl titanate, tetraisopropyl titanate, NACEM Iron (III), butyltin oxide, and dioctyltin dilaurate; and amine-based compounds, such as a trialkylamine, an N,N,N′,N′-tetraalkyldiamine, an N,N-dialkylamino alcohol, triethylenediamine, a morpholine derivative, and a piperazine derivative. Of those, dioctyltin dilaurate or triethylenediamine is preferred. When each of those cross-linking catalysts is used, the effect of the present invention becomes significant. The content ratio of the cross-linking catalyst is preferably from 0.01 part by weight to 3 parts by weight, more preferably from 0.02 part by weight to 1 part by weight with respect to 100 parts by weight of the acrylic polymer.

### C. Base Material

Examples of the base material include a resin sheet, a nonwoven fabric, paper, metal foil, a woven fabric, a rubber sheet, a foamed sheet, and laminates thereof (particularly a laminate including a resin sheet). As a resin for forming the resin sheet, there are given, for example, polyethylene terephthalate (PET), polyethylene naphthalate (PEN), polybutylene terephthalate (PBT), polyethylene (PE), polypropylene (PP), an ethylene-propylene copolymer, an ethylene-vinyl acetate copolymer (EVA), polyamide (nylon), wholly aromatic polyamide (aramid), polyimide (PI), polyvinyl chloride (PVC), polyphenylene sulfide (PPS), a fluorine-based resin, and polyether ether ketone (PEEK). Examples of the nonwoven fabric include: nonwoven fabrics of natural fibers each having heat resistance such as a nonwoven fabric containing Manila hemp; and nonwoven fabrics of synthetic resins, such as a nonwoven fabric of a polypropylene resin, a nonwoven fabric of a polyethylene resin, and a nonwoven fabric of an ester-based resin. Examples of the metal foil include copper foil, stainless-steel foil, and aluminum foil. Examples of the paper include Japanese paper and kraft paper. The base material is preferably formed of a resin excellent in heat resistance such as polyimide.

The thickness of the base material is preferably 1,000 μm or less, more preferably from 1 μm to 1,000 μm, still more preferably from 1 μm to 500 μm, particularly preferably from 3 μm to 300 μm, most preferably from 5 μm to 250 μm.

The base material may be subjected to surface treatment. Examples of the surface treatment include corona treatment, chromic acid treatment, ozone exposure, flame exposure, high-voltage electric shock exposure, ionizing radiation treatment, and coating treatment with an undercoating agent.

As an organic coating material, there are given, for example, materials described in “Plastic Hard Coat Material II” (CMC Publishing Co., Ltd., (2004)). A urethane-based polymer is preferably used, and polyurethane acrylate, polyester polyurethane, or a precursor thereof is more preferably used. This is because of the following reasons: any such material can be easily coated and applied onto the base material; and many kinds of the material can be industrially selected and are each available at low cost. The urethane-based polymer is, for example, a polymer formed of a reacted mixture of an isocyanate monomer and an alcoholic hydroxy group-containing monomer (e.g., a hydroxy group-containing acrylic compound or a hydroxy group-containing ester compound). The organic coating material may contain, as an optional additive, a chain extender such as polyamine, an age resistor, an oxidation stabilizer, or the like. The thickness of an organic coating layer is not particularly limited, but is suitably, for example, from about 0.1 μm to about 10 μm, preferably from about 0.1 μm to about 5 μm, more preferably from about 0.5 μm to about 5 μm.

### D. Method of Producing Pressure-Sensitive Adhesive Sheet

The pressure-sensitive adhesive sheet of the present invention may be produced by any appropriate method. The pressure-sensitive adhesive sheet of the present invention may be formed by, for example, coating (applying or drying) the acrylic pressure-sensitive adhesive on a predetermined supporting material to form a pressure-sensitive adhesive layer. The support may be a base material of the pressure-sensitive adhesive sheet or may be peeled after the formation of the pressure-sensitive adhesive layer. Various methods, such as bar coater coating, air knife coating, gravure coating, gravure reverse coating, reverse roll coating, lip coating, die coating, dip coating, offset printing, flexo printing, and screen printing, may each be employed as a coating method.

### EXAMPLES

Now, the present invention is specifically described by way of Examples. However, the present invention is by no means limited to these Examples. Evaluation methods in Examples are as described below. In addition, the terms “part(s)” and “%” in Examples are by weight unless otherwise stated.

### [Evaluation]

### (1) Pressure-Sensitive Adhesive Strength

PET #25 was bonded to one surface of the pressure-sensitive adhesive layer of a pressure-sensitive adhesive sheet to provide a measurement sample (width: 20 mm, length: 140 mm). The other surface of the pressure-sensitive adhesive layer of the measurement sample was bonded to SUS304 by one pass back and forth with a 2 kg roller. The obtained pressure-sensitive adhesive sheet with the adherend was allowed to stand for 30 minutes under an environment at 25° C., and was then set in a tensile tester (manufactured by Shimadzu Corporation, product name: “Shimadzu Autograph AG-120 kN”). The pressure-sensitive adhesive strength to the SUS304 was measured by a method in conformity with JIS Z 0237:2000 (bonding conditions: one pass back and forth with a 2 kg roller, tensile rate: 300 mm/min, peel angle: 180°, measurement temperature: 23° C.).

### (2) Weight-Average Molecular Weight of Base Polymer

The weight-average molecular weight Mw of a base polymer (acrylic polymer) was measured by gel permeation chromatography (GPC) (solvent: THF) using a calibration curve of standard polystyrene.

### (3) Coefficient of Thermal Expansion of Pressure-Sensitive Adhesive Layer

The coefficients of thermal expansion of a pressure-sensitive adhesive layer at from 200° C. to 210° C. and from 230° C. to 240° C. were measured with “TMA Q400” (manufactured by TA Instruments) in a tension mode under the conditions of a nitrogen gas flow rate of 50.0 ml/min and an applied load of 0.0196 N. Specifically, the measurement was performed by the following method.

Pressure-sensitive adhesive layers each having a thickness of 50 μm were formed by using the same pressure-sensitive adhesive as a pressure-sensitive adhesive used in each of Examples and Comparative Examples, and the pressure-sensitive adhesive layers were laminated to provide a sample having a thickness of 200 μm. The sample was punched into a size of 4 mm×30 mm, and was set to the “TMA Q400” probe with an interval of 8 mm therebetween. The dimensional change of the sample was measured while its temperature was increased from 20° C. to 300° C. at a temperature increase rate of 10° C./min. The slopes of the dimensional change at from 200° C. to 210° C. and from 230° C. to 240° C. were calculated from the obtained data to provide the values of the coefficients of thermal expansion.

### (4) Storage Elastic Modulus of Pressure-Sensitive Adhesive Layer

A storage elastic modulus G′ at a measurement frequency of 1 Hz, a strain of 0.05%, and 200° C. was measured with a dynamic viscoelasticity-measuring apparatus (manufactured by TA Instruments, product name: “ARES-G2”). Specifically, the measurement was performed by the following method.

Pressure-sensitive adhesive layers each having a thickness of 50 μm were formed by using the same pressure-sensitive adhesive as the pressure-sensitive adhesive used in each of Examples and Comparative Examples, and the pressure-sensitive adhesive layers were laminated to provide a sample having a thickness of 1 mm or more. The obtained sample was punched into a size of (8 mm, and was set to the “ARES-G2” probe. The temperature of the sample was increased from −50° C. to 260° C. at a temperature increase rate of 5° C./min, and a value of the storage elastic modulus G′ thereof at 200° C. was obtained.

### (5) 5% Weight Loss Temperature of Pressure-Sensitive Adhesive Layer

The temperature at which the weight of a pressure-sensitive adhesive layer was reduced by 5% was measured with a differential thermal analyzer (manufactured by TA Instruments, product name: “Discovery TGA”) under the conditions of a temperature increase rate of 10° C./min, a N2 atmosphere, and a gas flow rate of 25 ml/min. Specifically, the measurement was performed by the following method.

About 0.01 g of a pressure-sensitive adhesive layer sample was set in “Discovery TGA”. The weight loss of the pressure-sensitive adhesive sheet was measured while its temperature was increased from 20° C. to 500° C. at a temperature increase rate of 10° C./min. The temperature at which the weight loss became 5% was sampled from the obtained data.

### (6) Gel Fraction of Pressure-Sensitive Adhesive Layer

About 0.5 g of a pressure-sensitive adhesive layer was precisely weighed to provide a sample (weight: W1). The sample was wrapped with a porous polytetrafluoroethylene film (manufactured by Nitto Denko Corporation, product name: “Nitoflon NTF1122”, average pore diameter: 0.2 μm, porosity: 75%, thickness: 85 μm, weight: W2) in a drawstring bag shape, and an opening was tied with a string (weight: W3). The bag was immersed in 50 mL of toluene and held at room temperature (25° C.) for 7 days so that only a sol component in the pressure-sensitive adhesive layer was eluted out of the film. Then, the bag was taken out, and toluene adhering to an outer surface of the bag was wiped off. The bag was dried at 130° C. for 2 hours, and the weight (W4) of the bag was measured. Then, each value was substituted into the following equation to determine a gel fraction.

$$Gel fraction ( \% ) = [ ( W 4 - W 2 - W 3 ) / W 1 ] \times 100$$

(7) Film Shape Change Ratio after Heating in Oven at 240° C. for 5 Minutes

A pressure-sensitive adhesive sheet (size: 10 mm×50 mm) was fixed in an oven at 240° C. in the state of being hung in midair without sagging so that the distance between a lower side of the sheet and a base surface became 30 mm, and the pressure-sensitive adhesive sheet was allowed to stand for 5 minutes. Thus, a dimensional change by heating was measured. Dimensional stability in the case where the dimensional change amount was less than 20 mm was indicated by the symbol “∘”, and that in the case where the dimensional change amount was 20 mm or more was indicated by the symbol “×”.

### [Production Example 1] Production of Acrylic Polymer A

50 Parts by weight of butyl acrylate, 50 parts by weight of ethyl acrylate, 5 parts by weight of acrylic acid, 0.1 part by weight of 2-hydroxyethyl acrylate, 0.3 part by weight of trimethylolpropane triacrylate (TMPTA), and 0.1 part by weight of benzoyl peroxide serving as a polymerization initiator were added to toluene, and then the mixture was heated to 70° C. to provide a toluene solution of an acrylic polymer (polymer A).

### [Production Example 2] Production of Acrylic Polymer B

95 Parts by weight of 2-ethylhexyl acrylate, 5 parts by weight of acrylic acid, and 0.15 part by weight of benzoyl peroxide serving as a polymerization initiator were added to ethyl acetate, and then the mixture was heated to 70° C. to provide an ethyl acetate solution of an acrylic polymer (polymer B).

### [Production Example 3] Production of Acrylic Polymer C

30 Parts by weight of 2-ethylhexyl acrylate, 70 parts by weight of methyl acrylate, 10 parts by weight of acrylic acid, and 0.2 part by weight of benzoyl peroxide serving as a polymerization initiator were added to ethyl acetate, and then the mixture was heated to 70° C. to provide an ethyl acetate solution of an acrylic polymer (polymer C).

### [Production Example 4] Production of Acrylic Polymer D

30 Parts by weight of 2-ethylhexyl acrylate, 70 parts by weight of ethyl acrylate, 4 parts by weight of 2-hydroxyethyl acrylate, 5 parts by weight of methyl methacrylate, and 0.2 part by weight of benzoyl peroxide serving as a polymerization initiator were added to toluene, and then the mixture was heated to 70° C. to provide a toluene solution of an acrylic polymer (polymer D).

### [Production Example 5] Production of Acrylic Polymer E

100 Parts by weight of 2-ethylhexyl acrylate, 2 parts by weight of acrylic acid, 0.01 part by weight of trimethylolpropane triacrylate, and 0.2 part by weight of benzoyl peroxide serving as a polymerization initiator were added to toluene, and then the mixture was heated to 70° C. to provide a toluene solution of an acrylic polymer (polymer E).

### Example 1

The toluene solution of the polymer A (polymer A: 100 parts by weight) and 5 parts by weight of an epoxy-based cross-linking agent (manufactured by Mitsubishi Gas Chemical Company, Inc., product name: “TETRAD-C”) were mixed to prepare an acrylic pressure-sensitive adhesive.

The obtained acrylic pressure-sensitive adhesive was applied to a polyethylene terephthalate film with a silicone release agent-treated surface (thickness: 75 μm) so as to have a thickness of 5 μm after solvent volatilization (drying), and was then dried to form a pressure-sensitive adhesive layer on the polyethylene terephthalate film.

The pressure-sensitive adhesive layer was bonded to another polyethylene terephthalate film with a silicone release agent-treated surface (manufactured by Toray Industries, Inc., product name: “Cerapeel”, thickness: 38 μm) through lamination between rolls. Thus, a pressure-sensitive adhesive sheet sandwiched between the polyethylene terephthalate films with silicone release agent-treated surfaces was provided.

The resultant pressure-sensitive adhesive sheet was subjected to the above-mentioned evaluations. The results are shown in Table 1.

### Examples 2 to 10, and Comparative Examples 1 and 2

Pressure-sensitive adhesive sheets were obtained in the same manner as in Example 1 except that: polymers (base polymers), cross-linking agents, and cross-linking catalysts shown in Table 1 were used in blending amounts shown in Table 1; and the thicknesses of the pressure-sensitive adhesive layers (pressure-sensitive adhesive sheets) as shown in Table 1 were adopted. The resultant pressure-sensitive adhesive sheets were subjected to the above-mentioned evaluations. The results are shown in Table 1.

The isocyanate-based cross-linking agent used in Example 7 and the like is a product available under the product name “CORONATE L” manufactured by Nippon Polyurethane Industry Co., Ltd. In addition, the cross-linking catalyst used in Example 7 is dioctyltin dilaurate (manufactured by Tokyo Fine Chemical Co., Ltd., product name: “OL-1”).

TABLE 1

| Item | | | Example 1 | Example 2 | Example 3 | Example 4 | Example 5 | Example 6 |
|---|---|---|---|---|---|---|---|---|
| Pressure- | Pressure- | Kind of | Polymer A | Polymer A | Polymer A | Polymer A | Polymer B | Polymer C |
| sensitive | sensitive | polymer | | | | | | |
| adhesive | adhesive | | EA/BA/ | EA/BA/ | EA/BA/ | EA/BA/ | 2-EHA/ | 2EHA/MA/ |
| layer | | | AA/HEA/ | AA/HEA/ | AA/HEA/ | AA/HEA/ | AA = | AA = |
| | | | TMPTA = | TMPTA = | TMPTA = | TMPTA = | 95/5 | 30/70/10 |
| | | | 50/50/ | 50/50/ | 50/50/ | 50/50/ | | |
| | | | 5/0.1/0.3 | 5/0.1/0.3 | 5/0.1/0.3 | 5/0.1/0.3 | | |
| | | Carboxy | 4.7% | 4.7% | 4.7% | 4.7% | 5.0% | 9.1% |
| | | group- | | | | | | |
| | | containing | | | | | | |
| | | monomer | | | | | | |
| | | ratio [%] | | | | | | |
| | | Hydroxy | 0.1% | 0.1% | 0.1% | 0.1% | — | — |
| | | group- | | | | | | |
| | | containing | | | | | | |
| | | monomer | | | | | | |
| | | ratio [%] | | | | | | |
| | | TMPTA | 0.3% | 0.3% | 0.3% | 0.3% | — | — |
| | | content | | | | | | |
| | | ratio [%] | | | | | | |
| | | Weight- | 62.5 | 62.5 | 62.5 | 62.5 | 149 | 101 |
| | | average | | | | | | |
| | | molecular | | | | | | |
| | | weight Mw | | | | | | |
| | | of | | | | | | |
| | | polymer | | | | | | |
| | | [×10⁴] | | | | | | |
| | Cross- | Kind of | Epoxy-based | Epoxy-based | Epoxy-based | Epoxy-based | Epoxy-based | Epoxy-based |
| | linking | cross- | | | | | | |
| | agent | linking | | | | | | |
| | | agent | | | | | | |
| | | Number of | 5 | 5 | 5 | 1 | 5 | 1 |
| | | parts of | | | | | | |
| | | cross- | | | | | | |
| | | linking | | | | | | |
| | | agent | | | | | | |
| | Cross- | Number of | — | — | — | — | — | — |
| | linking | parts of | | | | | | |
| | catalyst | cross- | | | | | | |
| | | linking | | | | | | |
| | | catalyst | | | | | | |

| | | | | | | |
|---|---|---|---|---|---|---|
| Thickness [μm] | 5 | 30 | 100 | 50 | 50 | 50 |
| Pressure-sensitive | 0.2571 | 0.7696 | 2.2046 | 4.142 | 0.67 | 8.89 |
| adhesive strength [N/20 mm] | | | | | | |
| Storage elastic modulus | 0.10 | 0.10 | 0.10 | 0.06 | 0.11 | 0.23 |
| G′ (200) at 200° C. [MPa] | | | | | | |
| CTE at from 200° C. to | 32 | 32 | 32 | 46 | 43 | 32 |
| 210° C. [10⁻⁵/K] | | | | | | |
| CTE at from 230° C. to | 34 | 34 | 34 | 98 | 76 | 34 |
| 240° C. [10⁻⁵/K] | | | | | | |
| 5% weight loss | 360.7 | 360.7 | 360.7 | 343.0 | 350.3 | 314.0 |
| temperature [° C.] | | | | | | |
| Gel fraction [%] | 96.67 | 96.67 | 96.67 | 90.90 | 98.10 | 96.61 |
| Dimensional change of | 0 | 1 | 2 | 4 | 2 | 2 |
| resin sheet [mm] | | | | | | |
| Dimensional stability at | ∘ | ∘ | ∘ | ∘ | ∘ | ∘ |
| high temperature [∘/x] | | | | | | |
| ∘ . . . less than 20 mm, | | | | | | |
| x . . . 20 mm or more | | | | | | |

| | | | | | | | Comparative | Comparative |
|---|---|---|---|---|---|---|---|---|
| Item | | | Example 7 | Example 8 | Example 9 | Example 10 | Example 1 | Example 2 |
| Pressure- | Pressure- | Kind of | Polymer D | Polymer D | Polymer E | Polymer E | Polymer C | Polymer D |
| sensitive | sensitive | polymer | 2EHA/EA/ | 2EHA/EA/ | 2-EHA/ | 2-EHA/ | 2EHA/ | 2EHA/EA/ |
| adhesive | adhesive | | MMA/HEA = | MMA/HEA = | AA/TMPTA = | AA/TMPTA = | MA/AA = | MMA/HEA = |
| layer | | | 30/70/5/4 | 30/70/5/4 | 100/2/0.01 | 100/2/0.01 | 30/70/10 | 30/70/5/4 |
| | | Carboxy | — | — | 2.0% | 2.0% | 9.1% | — |
| | | group- | | | | | | |
| | | containing | | | | | | |
| | | monomer | | | | | | |
| | | ratio [%] | | | | | | |
| | | Hydroxy | 3.7% | 3.7% | — | — | — | 3.7% |
| | | group- | | | | | | |
| | | containing | | | | | | |
| | | monomer | | | | | | |
| | | ratio [%] | | | | | | |
| | | TMPTA | — | — | 0.01% | 0.01% | — | — |
| | | content | | | | | | |
| | | ratio [%] | | | | | | |
| | | Weight- | 45 | 45 | 70 | 70 | 101 | 45 |
| | | average | | | | | | |
| | | molecular | | | | | | |
| | | weight Mw | | | | | | |
| | | of | | | | | | |
| | | polymer | | | | | | |
| | | [×10⁴] | | | | | | |
| | Cross- | Kind of | Isocyanate-based | Isocyanate-based | Epoxy-based | Epoxy-based | Epoxy-based | Isocyanate-based |
| | linking | cross- | | | | | | |
| | agent | linking | | | | | | |
| | | agent | | | | | | |
| | | Number of | 3 | 3 | 2 | 1 | 0.1 | 1 |
| | | parts of | | | | | | |
| | | cross- | | | | | | |
| | | linking | | | | | | |
| | | agent | | | | | | |
| | Cross- | Number of | 0.05 | — | — | — | — | — |
| | linking | parts of | | | | | | |
| | catalyst | cross- | | | | | | |
| | | linking | | | | | | |
| | | catalyst | | | | | | |

| | | | | | | |
|---|---|---|---|---|---|---|
| Thickness [μm] | 50 | 50 | 50 | 50 | 50 | 50 |
| Pressure-sensitive | 3.12 | 4.87 | 0.19 | 0.9 | 19.8 | 9.64 |
| adhesive strength [N/20 mm] | | | | | | |
| Storage elastic modulus | 0.25 | 0.13 | 0.14 | 0.09 | 0.06 | 0.04 |
| G′ (200) at 200° C. [MPa] | | | | | | |
| CTE at from 200° C. to | 65 | 119 | 31 | 39 | 518 | 1,047 |
| 210° C. [10⁻⁵/K] | | | | | | |
| CTE at from 230° C. to | 75 | 169 | 47 | 319 | N.D. (>3,000) | N.D. (>3,000) |
| 240° C. [10⁻⁵/K] | | | | | | |
| 5% weight loss | 318.1 | 333.4 | 327.6 | 324.1 | 315.6 | 339.3 |
| temperature [° C.] | | | | | | |
| Gel fraction [%] | 96.87 | 94.16 | 95.18 | 93.07 | 93.16 | 81.44 |
| Dimensional change of | 5 | 10 | 4 | 15 | 25 | 22 |
| resin sheet [mm] | | | | | | |
| Dimensional stability at | ∘ | ∘ | ∘ | ∘ | x | x |
| high temperature [∘/x] | | | | | | |
| ∘ . . . less than 20 mm, | | | | | | |
| x . . . 20 mm or more | | | | | | |

As apparent from Table 1, the pressure-sensitive adhesive sheet of the present invention having a coefficient of thermal expansion (CTE) that falls within a specific range is excellent in dimensional stability under high temperature. In addition, the pressure-sensitive adhesive sheet of the present invention is advantageous also in that the pressure-sensitive adhesive sheet has a low 5% weight loss temperature, that is, the pressure-sensitive adhesive sheet hardly undergoes thermal decomposition and is reduced in outgas even under high temperature.

### REFERENCE SIGNS LIST

10 pressure-sensitive adhesive layer
20 base material
100 pressure-sensitive adhesive sheet

1. A pressure-sensitive adhesive sheet for temporarily fixing an electronic part, comprising a pressure-sensitive adhesive layer containing an acrylic pressure-sensitive adhesive,
wherein the acrylic pressure-sensitive adhesive contains an acrylic polymer, and
wherein the pressure-sensitive adhesive layer has a coefficient of thermal expansion at from 200° C. to 210° C. of from 1×10⁻⁵/K to 500×10⁻⁵/K.

2. The pressure-sensitive adhesive sheet for temporarily fixing an electronic part according to claim 1, wherein the pressure-sensitive adhesive layer has a coefficient of thermal expansion at from 230° C. to 240° C. of from 1×10⁻⁵/K to 500×10⁻⁵/K.

3. The pressure-sensitive adhesive sheet for temporarily fixing an electronic part according to claim 1, wherein the pressure-sensitive adhesive layer has a storage elastic modulus G′ at 200° C. of 0.05 MPa or more.

4. The pressure-sensitive adhesive sheet for temporarily fixing an electronic part according to claim 1, wherein the pressure-sensitive adhesive layer has a 5% weight loss temperature of from 320° C. to 400° C.

5. The pressure-sensitive adhesive sheet for temporarily fixing an electronic part according to claim 1, wherein the pressure-sensitive adhesive layer has a gel fraction of from 93% to 99.99%.

6. The pressure-sensitive adhesive sheet for temporarily fixing an electronic part according to claim 1,
wherein the pressure-sensitive adhesive layer further contains an epoxy-based cross-linking agent, and
wherein the acrylic polymer contains a constituent unit derived from a carboxy group-containing monomer.

7. The pressure-sensitive adhesive sheet for temporarily fixing an electronic part according to claim 1,
wherein the pressure-sensitive adhesive layer further contains an isocyanate-based cross-linking agent, and
wherein the acrylic polymer contains a constituent unit derived from a hydroxy group-containing monomer.

8. The pressure-sensitive adhesive sheet for temporarily fixing an electronic part according to claim 1, wherein the acrylic polymer contains a constituent unit derived from a polyfunctional monomer.

9. The pressure-sensitive adhesive sheet for temporarily fixing an electronic part according to claim 8, wherein the polyfunctional monomer is trimethylolpropane triacrylate.

10. The pressure-sensitive adhesive sheet for temporarily fixing an electronic part according to claim 1, wherein the acrylic pressure-sensitive adhesive further contains a cross-linking catalyst.

11. The pressure-sensitive adhesive sheet for temporarily fixing an electronic part according to claim 10, wherein the cross-linking catalyst is dioctyltin dilaurate or triethylenediamine.

12. The pressure-sensitive adhesive sheet for temporarily fixing an electronic part according to claim 1, wherein the acrylic polymer has a weight-average molecular weight Mw of from 600,000 to 1,600,000.

13. The pressure-sensitive adhesive sheet for temporarily fixing an electronic part according to claim 1, further comprising a base material,
wherein the pressure-sensitive adhesive layer is arranged on at least one surface of the base material.

14. The pressure-sensitive adhesive sheet for temporarily fixing an electronic part according to claim 1, wherein the pressure-sensitive adhesive sheet is used in a flip-chip bonding step, a resin encapsulation step, and a rewiring layer formation step for a semiconductor device.
